(19) United States
(12) Patent Application Publication
(10) Pub. No.: US 2008/0064195 A1
(43) Pub. Date: Mar. 13, 2008

(54) Method for Manufacturing Gate of Non Volatile Memory Device

(76) Inventor: Young-Ju Kim, Seongnam-si (KR)

Correspondence Address: Frank Chau, Esq.;F. CHAU & ASSOCIATES, LLC, 130 Woodbury Road, Woodbury, NY, 11797, US

(21) Appl. No.: 11/750,059

(22) Filed: May 17, 2007

(30) Foreign Application Priority Data
Aug. 29, 2006 (KR) 2006-0082386

(51) Int. Cl. H01L 21/3205

(52) U.S. Cl. 438/591; 257/E21.294

(57) ABSTRACT

A method for manufacturing the gate of the non-volatile memory device is characterized in in-situ etching a tungsten silicide film, polycrystalline silicon films, an ONO film, and a silicon oxide film with one step using one etchant having a lower etch selectivity on the silicon and oxide films in order to form the gate. As such, in-situ etching the material films for forming the gate with one step using an etchant having a low etch selectivity on the silicon and oxide films can prevent undercuts from occurring on an interface between two different material films to thereby improve cell distribution, minimize the occurrence of particles, and reduce processing time over a prior art.

### CROSS-REFERENCE TO RELATED FOREIGN APPLICATIONS

The present application claims priority from Korean Patent Application. No. 10-2006-0082386, filed in Korea on Aug. 29, 2006, the entire contents of which are herein incorporated by reference.

### BACKGROUND

1. Field of the Invention

The present disclosure is directed to a method for manufacturing a non-volatile memory device, and more specifically, to a method for manufacturing a gate of a non-volatile memory device.

2. Description of the Background Art

Semiconductor memory devices used for storing data can foe classified into volatile memory devices and non-volatile memory devices. Among these memory devices, the volatile memory devices, which are represented by DRAM (Dynamic Random Access Memory) or SRAM (Static Random Access Memory), are advantageous in that they have fast data input/output speeds, but are disadvantageous in that they can lose data stored therein as the supply of electric power is cut off. On the contrary, the non-volatile memory devices, which are represented by EPROM (Erasable Programmable Read Only Memory) or EEPROM (Electrically Erasable Programmable Read Only Memory), have a merit in that they can retain data stored therein even when the supply of electric power is stopped although the data input/output speeds are slower than those of the volatile memory. Accordingly, these non-volatile memory devices can foe widely used for memory cards for storing music or video data or mobile communication systems which can not always supply electric power or intermittently stop the supply of electric power.

On the other hand, these flash memory devices, especially flash memory devices employing a Tr/1 cell structure having collectively erasable characteristics for improved integration have been expected to replace existing hard disks for PCs since they are capable of performing electrical data input/output freely, have a small power consumption, as well as allow a programmer to make a program swiftly. Therefore, the demands for flash memory devices are on the rise. A flash memory device can be divided into a NOR-type flash memory, where two or more cell transistors are connected in parallel with each other on a bit line, and a NAND-type flash memory, where two or more cell transistors are connected in serial with each other on a bit line. In spite of the fact that a flash memory can store data continuously even when the supply of electric power is cut off, however, its operation speed is slower than a volatile memory. Therefore, various cell structures and their driving methods have been studied to improve a programming speed and an erase speed of a flash memory device.

In particular, the NOR-type flash memory device has a structure in which plural memory cells composed of single transistors are connected in parallel with each other on a bit line and a memory cell transistor is connected between a drain connected to the bit line and a source connected to a common source line, and is capable of performing a high-speed operation while increasing currents of memory cells but has difficulty in high integration due to the increase of areas occupied by bit line contacts and source line.

In accordance with a tendency to high integration and high capacity for a semiconductor device, the size of each unit device configuring a memory cell is reduced and accordingly a technology of implementing high integration which forms a multi-layered structure in a restricted area has also continued to be improved. A stacked-gate structure has been widely employed as a way for implementing high integration. The stacked-gate structure is a structure in which a tunnel oxide film, e.g. formed of a silicon oxide film, a floating gate formed of polycrystalline silicon, a gate interlayer dielectric film formed of an ONO (Oxide-Nitride-Oxide) film, and a control gate film formed of polycrystalline silicon are sequentially stacked.

The floating gate is completely insulated and isolated electrically from the outside, and may store data using a characteristic that currents of memory cells are changed according to inflow and outflow of electrons into and out of the floating gate. The inflow (program) into the floating gate is done using a F-N (Fowler Nordheim) tunneling method through the gate interlayer dielectric film between the floating gate and control gate or using a CHEI (Channel Hot Electron Injection) method using high temperature electrons in channels. The outflow (erase) of the electrons flowing through the floating gate is performed using a F-N (Fowler-Nordheim) tunneling method through the gate interlayer dielectric film between the floating gate and control gate. At this time, the F-N tunneling is created by applying an electric field of 6˜8 MV/cm to the tunnel oxide film provided between the floating gate and semiconductor substrate. The electric field between the floating gate and semiconductor substrate is generated by applying a high voltage of 15˜20V to the control gate positioned on the upper side of the floating gate. Accordingly, it is needed to increase a coupling ratio of unit cells configuring a flash memory device so as to reduce the program voltage and erase voltage. Variables determining the coupling ratio are the capacitance of the tunnel oxide film and the capacitance of the gate interlayer dielectric film formed of an ONO film as represented in Equation 1.

CR=Ci/(Ci+Ct), [Equation 1]

where, Ci indicates capacitance of the gate interlayer dielectric film and Ct indicates capacitance of the tunnel oxide film.

The magnitudes of Ci and Ct are proportional to the area of the floating gate and inversely-proportional to its thickness. Therefore, as the thickness of the floating gate becomes thinner and its area becomes broader, the electric property of the flash memory device would be better.

FIGS. 1a to 1f show a process forming a gate of a flash memory device according to a prior art.

Referring first to FIG. 1a, a device separation film (not shown) is formed by carrying out a typical STI (Shallow Trench Isolation) process on a semiconductor substrate 10 doped with N-type or P-type impurities.

Subsequently, on the upper side of the semiconductor substrate 10 are sequentially deposited a silicon oxide film 12, a first polycrystalline silicon film 14, an ONO film 16, a second polycrystalline silicon film 18, and a tungsten silicide film 20. Then, a photosensitive film pattern 22 is formed by applying a typical photolithography process on the upper side of the tungsten silicide film 20.

Referring to FIG. 1b, a tungsten silicide pattern 20-1 is formed by performing anisotropic etching using the photosensitive film pattern 22 as an etching mask. At this time, an et chant, e.g. a gas mixture of SF₆/Cl₂, is used to perform the anisotropic etching on the tungsten silicide film 20.

Referring to FIG. 1c, a control gate 18-1 is formed by performing anisotropic etching on the second polycrystalline silicon film 18 using the tungsten silicide pattern 20-1 as an etching mask. At this time, an etchant, e.g. a gas mixture of HBr/O₂/He/HeO₂, is used to perform the anisotropic etching on the second polycrystalline silicon film 18.

Referring to FIG. 1d, a gate interlayer dielectric film 16-1 is formed by performing anisotropic etching on the OHO film 16 using the control gate 18-1 as an etching mask. At this time, an etchant, e.g. a gas mixture of CHF₃/Ar, is used to perform, the anisotropic etching on the ONO film 16. Referring to FIG. 1e, a floating gate 14-1 is formed by performing anisotropic etching on the first polycrystalline silicon film 14 using the control gate 18-1 and gate interlayer dielectric film 16-1 as an etching mask. At this time, an etchant, e.g. a gas mixture of HBr/O₂/He/HeO₂, is used to perform the anisotropic etching on the first polycrystalline silicon film 14.

Referring to FIG. 1f, a tunnel oxide film 12-1 is formed by performing anisotropic etching on the silicon oxide film 12 using the control gate 18-1, gate interlayer dielectric film 16-1, and floating gate 14-1 as an etching mask.

In the prior art as shown in FIGS. 1a to 1f, a stacked-gate structure of a flash memory device composed of the tungsten silicide 20-1, control gate 18-1, gate interlayer dielectric film 16-1, floating gate 14-1, and tunnel oxide film 12-1 has been complete by sequentially carrying out separate anisotropic etching processes on the tungsten silicide film 20, second polycrystalline silicon film 18, ONO film 16, first polycrystalline silicon film 14, and silicon oxide film 12 using different etchants. At this time, each etchant, i.e. gas mixtures of SF₆/Cl₂, CHF₃/Ar and HBr/O₂/HeO₂/He used to perform anisotropic etching on the tungsten silicide film 20, second polycrystalline silicon film 18, ONO film 16, first polycrystalline silicon film 14, and silicon oxide film 12 were very good chemicals, each having high etch selectivity for each targeted film to be etched. Therefore, the gas mixtures of SF₆/Cl₂, CHF₃/Ar and HBr/O₂/HeO₂/He showed high etching efficiency in etching the tungsten silicide film, first polycrystalline silicon film, second polycrystalline silicon film, and ONO film. However, in case of using the gas mixtures of SF₆/Cl₂, CHF₃/Ar and HBr/O₂/HeO₂/He to carry out an anisotropic etching process on each of the tungsten silicide film, first polycrystalline silicon film and second polycrystalline silicon film 18, and ONO film 16, there has occurred a situation that the high etch selectivity for other films caused undercuts on an interface between two adjoining films (i.e. between the control floating gate 18-1 and gate interlayer dielectric film 16-1, between the gate interlayer dielectric film 16-1 and floating gate 14-1, and between the floating gate and tunnel oxide film). In the gate pattern of the stacked structure, interfaces between the control gate 18-1, gate interlayer dielectric film 16-1, and floating gate 14-1 are an important factor characterising how unit cells, which configure a flash memory device, are dispersed. Undercuts created on an interface between two adjoining films (i.e. between the control floating gate 18-1 and gate interlayer dielectric film 16-1, between the gate interlayer dielectric film 16-1 and floating gate 14-1, and between the floating gate and tunnel oxide film 12-1), may cause the size of the gate pattern to be uneven and cells to be increasingly scattered from one another, which in tarn can degrade productivity and reliability of the whole semiconductor memory devices.

In addition, in a case where the anisotropic etching processes for patterning the tungsten silicide film 20, second polycrystalline silicon film 18, ONO film 16, first polycrystalline silicon film 14, and silicon oxide film 12 are carried out in different process chambers over several steps, the full processing time is lengthened.

Moreover, in terms of a wafer, an etchant used for etching processes contains particles. Therefore, in a case where the anisotropic etching processes for patterning the tungsten silicide film 20, second polycrystalline silicon film 18, ONO film 16, first polycrystalline silicon film 14, and silicon oxide film 12 are carried out over several steps with different etchants as in the prior art, equipment for etching as well as wafers can be contaminated with the particles, and this can degrade electric properties and throughput of semiconductor memory devices.

### SUMMARY OF THE INVENTION

According to an aspect of the present invention, there is provided a method for manufacturing a gate of a semiconductor memory device comprising: forming a stacked material film including a plurality of insulating films and conductive films on an upper side of a semiconductor substrate; and performing an anisotropic etching process on the stacked material film including the plurality of insulating films and conductive films with one etching process using an etchant having a low etch selectivity on the insulating films and conductive films constituting the stacked material film.

According to another aspect of the present invention, there is provided a method for manufacturing a gate of a non-volatile memory device, comprising: forming a stacked material film including a plurality of insulating films and conductive films on an upper side of a semiconductor substrate; and performing an anisotropic etching process on the stacked material film including the plurality of insulating films and conductive films sequentially from above to below using an etchant having a low etch selectivity on the insulating films and conductive films constituting the stacked material film after the stacked material film is formed on the semiconductor substrate.

### BRIEF DESCRIPTION OF THE DRAWINGS

The above aspects will be more apparent by describing certain exemplary embodiments of the present invention with reference to the accompanying drawings.

FIGS. 1a to 1f show a process forming a gate of a flash memory device according to a prior art.

FIGS. 2a to 2c show a process forming a gate of a flash memory device using an in-situ etching process according to an embodiment of the present invention.

FIG. 3 shows an etch rate of polycrystalline silicon depending on increase of HBr in an etchant (CF₄/He/HBr) used for an etching process according to an embodiment of the present invention.

FIG. 4 shows an etch rate of polycrystalline silicon depending on increase of He in an etchant (CF₄/He/HBr) used for an etching process according to an embodiment of the present invention.

FIG. 5 shows an etch selectivity for polycrystalline silicon and silicon oxide films depending on the amount of He in an etchant (CF₄/He/HBr) used for an etching process according to an embodiment of the present invention.

FIG. 6 shows an etch rate of polycrystalline silicon depending on increase of pressure in an etching process according to an embodiment of the present invention.

FIG. 7 shows an etch rate of polycrystalline silicon depending on increase of electric power in an etching process according to an embodiment of the present invention.

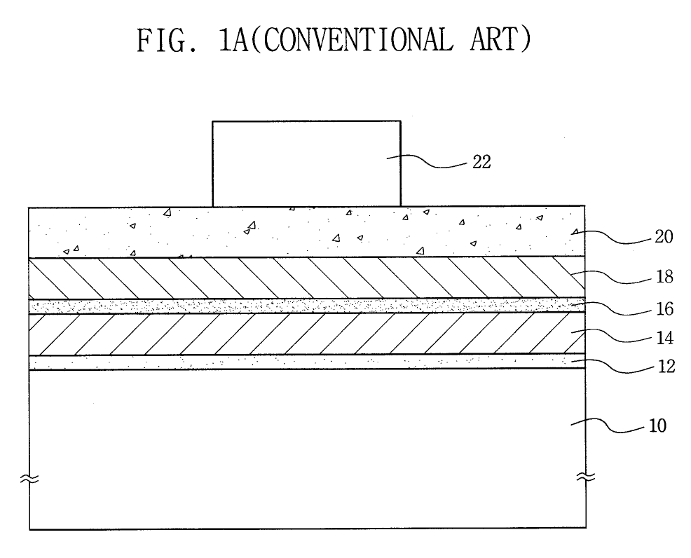

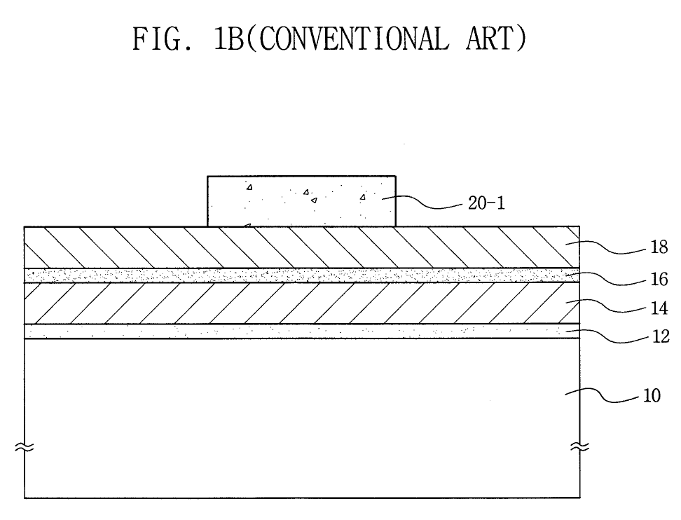

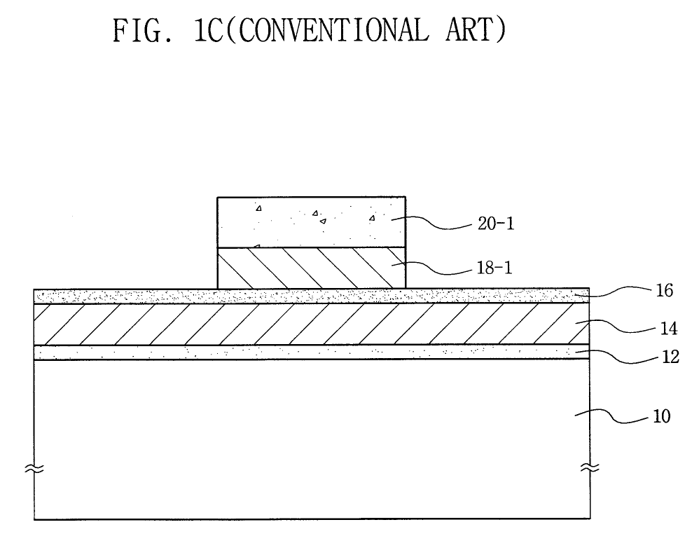

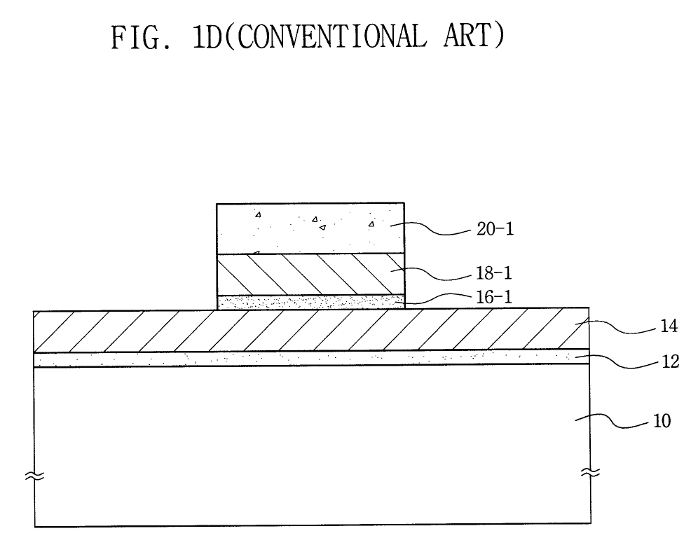

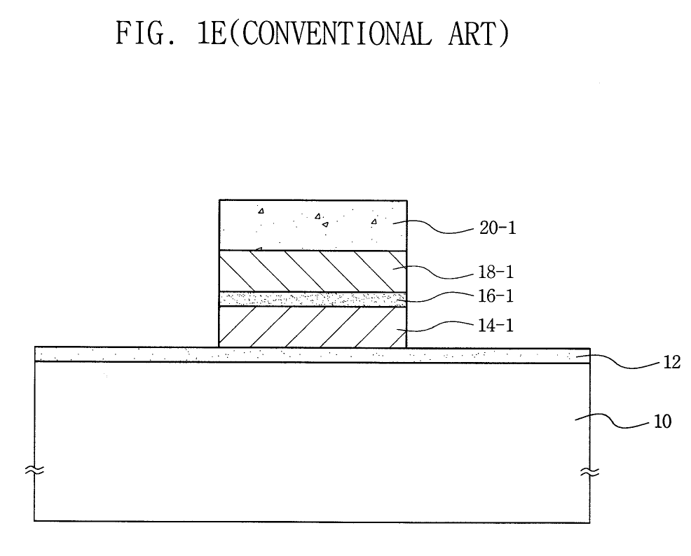

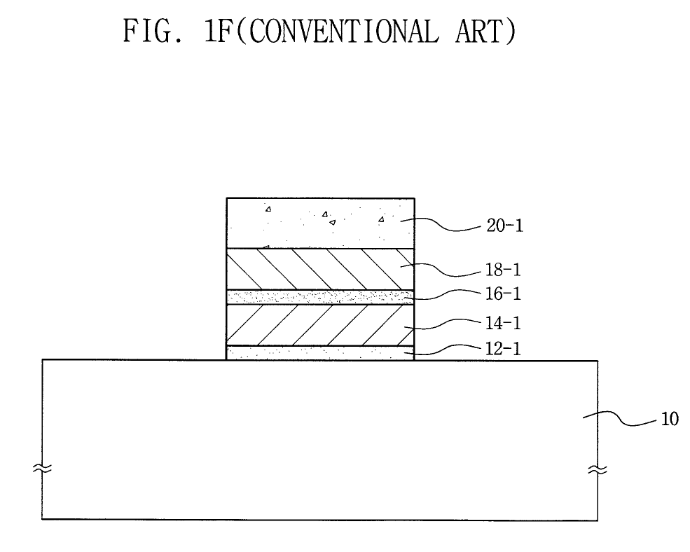

### DETAILED DESCRIPTION OF THE EXEMPLARY EMBODIMENTS

Hereinafter, exemplary embodiments of the present invention will be described in detail with reference to the accompanying drawings. However, the present invention is not limited to the embodiments disclosed hereinafter, but can be implemented in diverse forms. In the entire description of the present invention, the same drawing reference numerals are used for the same elements across various figures.

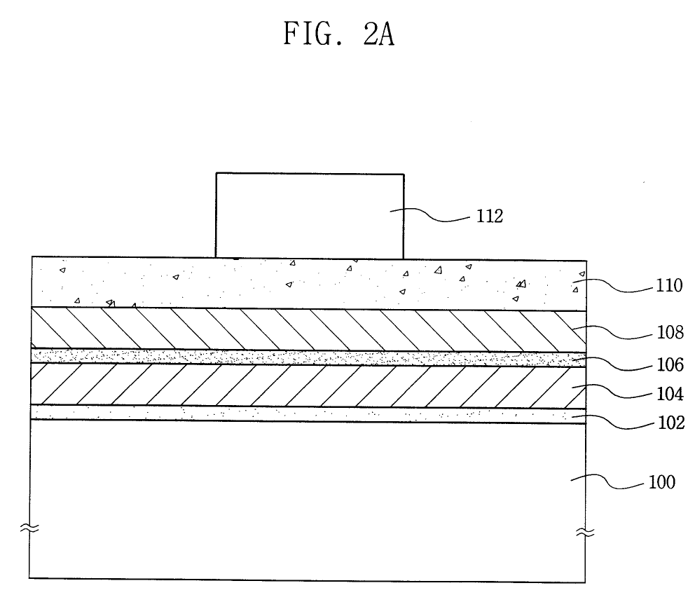

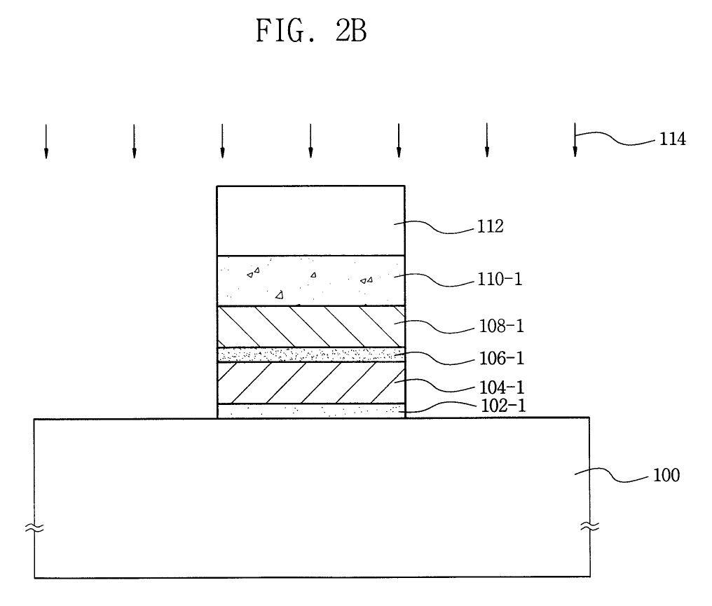

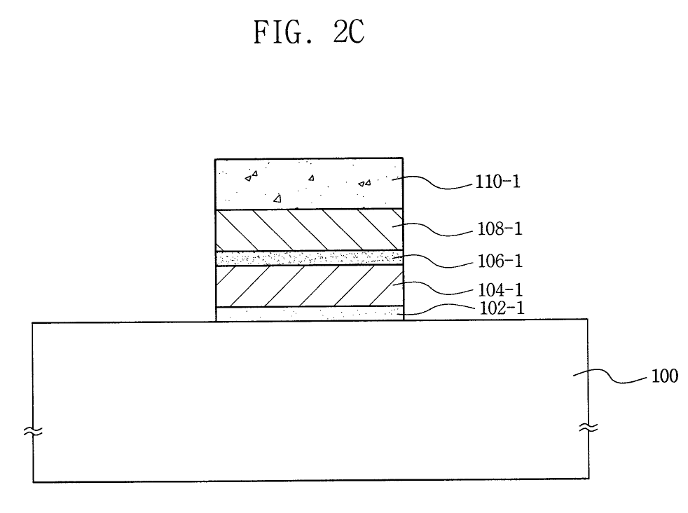

FIGS. 2a to 2c show a process forming a gate applicable to a NOR type or HAND type flash memory device according to an embodiment of the present invention.

First, FIG. 2a illustrates a cross sectional view of a semiconductor substrate on which a plurality of layers are deposited to form a gate of a flash memory device.

Referring to FIG. 2a, a device separation film (not shown) is formed by carrying out a typical SIX (Shallow Trench Isolation) process on a semiconductor substrate 100 doped with N-type or P-type impurities. Subsequently, on the upper side of the semiconductor substrate 100 are sequentially deposited a silicon oxide film 102, a first polycrystalline silicon film 104, an ONO film 106, a second polycrystalline silicon film 108, and a tungsten silicide film 110.

The silicon oxide film 102 is deposited to a of approximately 100˜200 Å, and more specifically, 150 Å. The first polycrystalline silicon film 104 is deposited to a thickness of approximately 600˜1000 Å, and more specifically, 800 Å. The OHO film 106 is deposited to a thickness of approximately 200˜250 Å, and more specifically, 240 Å. The second polycrystalline silicon film 108 is deposited to a thickness of approximately 500˜700 Å, and more specifically, 600 Å. The tungsten silicide film 110 is deposited to a thickness of approximately 800˜1200 Å, and more specifically, 1000 Å.

Then, a hard mask 112 is disposed on the upper side of the tungsten silicide film 110. The hard mask 112 may be formed through a typical photolithography process using a photosensitive film.

The hard mask 112 formed through a typical photolithography process is an etching mask for etching the underlying material films (e.g. the second polycrystalline silicon film 108, ONO film 106, etc.) upon an in-situ etching process according to an embodiment of the present invention. The hard mask 112 can be formed as a stacked structure in which a lower antireflection film (e.g. SiON), a PEOX film, and an upper antireflection film (e.g. SiON) are sequentially deposited. The lower antireflection film, PEOX film, and upper antireflection film each may be deposited to thicknesses of 240 Å, 1900 Å, and 600 Å.

FIG. 2b illustrates a process forming a gate of a flash memory device through an in-situ process according to an embodiment of the present invention.

Referring to FIG. 2b, an etching process (114) is applied on a semiconductor substrate 100 formed with the hard mask 112 using a mixture gas composed of CF₄/He/HBr as an etching etchant. The etching process 114 according to an embodiment of the present invention is a plasma etching process that performs in a vertical direction an anisotropic etching on the silicon oxide film 102, first polycrystalline silicon film 104, ONO film 106, second polycrystalline silicon film 108, and tungsten silicide film 110 deposited on the upper side of the semiconductor substrate 100. The etching process 114 performs an in-situ etching on the silicon oxide film 102, first polycrystalline silicon film 104, ONO film 106, second polycrystalline silicon film 108, and tungsten silicide film 110 using a gas mixture gas of CF₄/He/HBr as an etchant. It has been found that the mixture gas of CH₄/He/HBr used as an etchant in the in-situ etching process has a property capable of etching an oxide film, a nitride film, and a silicon film in an even manner with a minimum selectivity. Accordingly, the silicon oxide film 102 formed of an oxide film, the ONO film formed of an oxide film and a nitride film, a polycrystalline silicon film containing a silicon component, and the tungsten silicide film can be in-situ etched in a process chamber with one step using a gas mixture of CF4/He/HBr. In addition, attacks from particles can be minimized and processing time can foe further reduced by performing the in-situ process within a process chamber with one step using one etchant.

Hereinafter, the in-situ etching process according to the present invention will be described in more detail. First, the semiconductor substrate 100, on which is deposited the silicon oxide film 102, first polycrystalline silicon film 104, ONO film 106, second polycrystalline silicon film 108, and tungsten silicide film 110, is placed into a process chamber. Then, CF₄, He, and HBr as an etchant are injected into the process chamber. Subsequently, the silicon oxide film 102, a first polycrystalline silicon film 104, an ONO film 106, a second polycrystalline silicon film 108, and a tungsten silicide film 110, which are placed on the upper side of the semiconductor substrate 100 are etched sequentially from above to below according to the stacking order by creating plasma within the process chamber. The flux of the etchant composed of CF₄, He, and HBr may be maintained at 1-500 SCCM. More specifically, the flux of CF₄ may be maintained at 15-80 SCCM, the flux of He at 50-200 SCCM, and the flux of HBr at 100-300 SCCM. In addition, the RF power may be maintained at 50-1000 W and pressure may be maintained at 5-100 mT within the process chamber to create plasma within the process chamber.

If an in-situ etching process is done under the above conditions, then the tungsten silicide film 110 is first anisotropically-etched by the etchant composed of CF₄, He, and HBr. Next, the second polycrystalline silicon film 108 exposed by the anisotropic etching of the tungsten silicide film 110 is anisotropically-etched. Subsequently, the ONO film 106 exposed by the anisotropic etching of the second polycrystalline silicon film 108 is etched and then the first polycrystalline silicon film 104 exposed by the anisotropic etching of the ONO film 106 is etched. Finally, the silicon oxide film 102 exposed by the anisotropic etching of the first polycrystalline silicon film 104 is etched. As such, the tungsten silicide film 110, the second polycrystalline silicon film 108, the ONO film 106, the first polycrystalline silicon film 104, and the silicon oxide film 102 are etched within a process chamber sequentially from above to below according to the stacking order.

Then, eliminating the hard disk 112, as shown in FIG. 2c, completes a gate structure of a flash memory device composed of a tunnel oxide film 102-1, a floating gate 104-1, a gate interlayer film 106-1, a control gate 108-1, and a tungsten silicide 110-1.

As can be seen from the above descriptions, an embodiment of the present invention can perform an in-situ etching on the tungsten silicide film 110, the second polycrystalline silicon film 108, the ONO film 106, the first polycrystalline silicon film 104, and the silicon oxide film 102 using a gas mixture of CF₄/He/HBr as an etchant within one process chamber from above to below according to the stacking order of the above material films in order to form a gate structure of a flash memory device. The etchant composed of CF₄/He/HBr used for an in-situ etching process according to an embodiment of the present invention has a low etch selectivity over silicon and oxide film. It is possible to prevent undercuts from occurring on an interface between two different material films to improve cell distribution upon etching the tungsten silicide film 110, the second polycrystalline silicon film 108, the ONO film 106, the first polycrystalline silicon film 104, and the silicon oxide film 102.

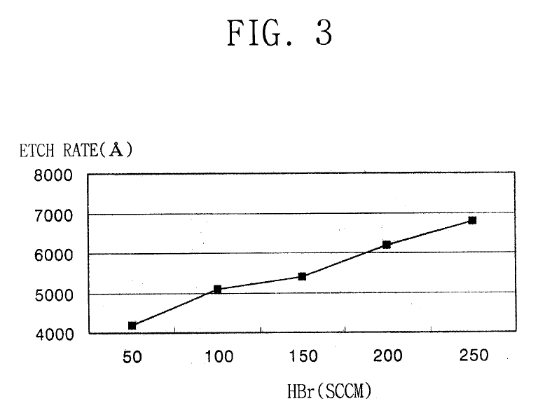

FIGS. 3 to 7 show the results of experiments for finding the etchant applied to an in-situ process of the present invention on a specific material film.

FIG. 3 illustrates an etch rate of polycrystalline silicon depending on increase of HBr in an etchant (CF₄/He/HBr).

Referring to FIG. 3, it can be seen that the etch rate on polycrystalline silicon films 104, 108, which function as a floating gate and a control gate, continuously increases as the amount of HBr increases.

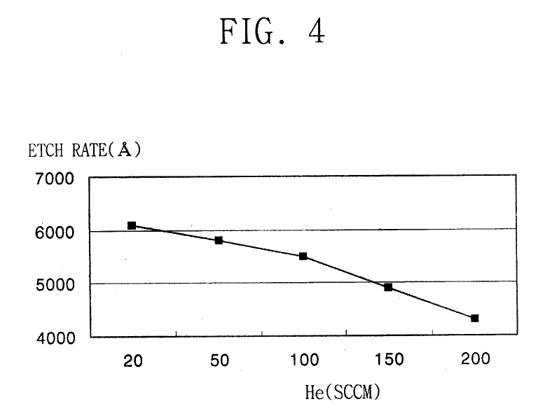

FIG. 4 illustrates an etch rate of polycrystalline silicon depending on increase of He in an etchant (CF₄/He/HBr).

Referring to FIG. 4, it can be seen that the etch rate on the polycrystalline silicon films 104, 108, which function as a floating gate and a control gate, continuously decreases as the amount of He increases.

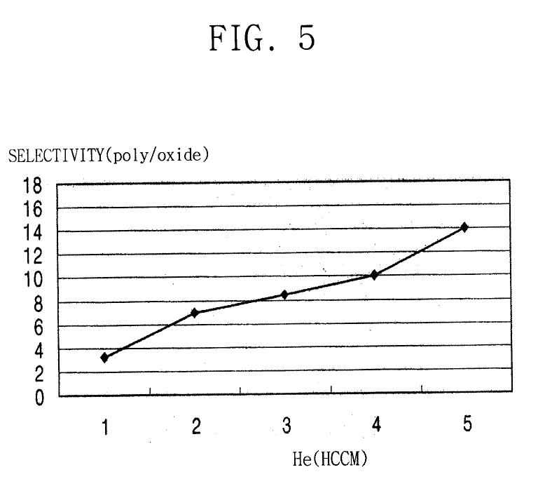

FIG. 5 illustrates an etch selectivity for polycrystalline silicon and silicon oxide films depending on the amount of He in an etchant (CF₄/He/HBr).

Referring to FIG. 5, it can be seen that each etch selectivity on the polycrystalline silicon films 104, 108, forming a floating gate and a control gate, and the silicon oxide film 102 forming a tunnel oxide film, increases as the amount of He increases.

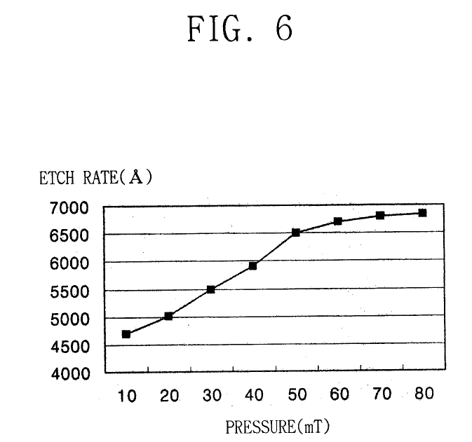

FIG. 6 illustrates an etch rate of polycrystalline silicon depending on an increase of pressure.

Referring to FIG. 6, it can be seen that the etch rate on polycrystalline silicon films 104, 108, which function as a floating gate and a control gate, continuously increases as pressure within a process chamber performing an in-situ etching process according to an embodiment of the present invention increases.

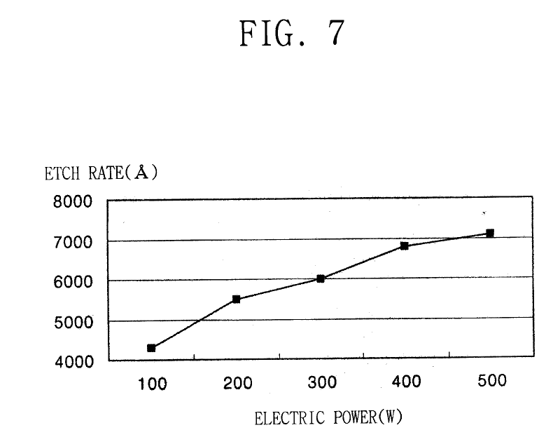

FIG. 7 illustrates an etch rate of polycrystalline silicon depending on an increase of electric power.

Referring to FIG. 7, it can be seen that the etch rate on polycrystalline silicon films 104, 108, which function as a floating gate and a control gate, continuously increases as RF electric power within a process chamber performing an in-situ etching process according to an embodiment of the present invention increases.

It can be seen through the results of the experiments shown in FIGS. 3 to 5 that among the etchant (CF₄/He/HBr) components applied to the in-situ etching process according to the present invention, HBr increases the etch rate on polycrystalline silicon, He decreases the etch rate on polycrystalline silicon, and He increases the etch selectivity on polycrystalline silicon and silicon oxide film. However, a mixture of CF₄, He, and HBr leads to low etch selectivity on polycrystalline silicon and silicon oxide film.

Therefore, the present invention performs an in-situ etching process on the tungsten silicide film 110, the second polycrystalline silicon film 108, the OHO film 106, the first polycrystalline silicon film 104, and the silicon oxide film 102 stacked sequentially on the upper side of the semiconductor substrate 100 using this property of CF₄/He/HBr. As such, in the case that the tungsten silicide film 110, the second polycrystalline silicon film 108, the ONO film 106, the first polycrystalline silicon film 104, and the silicon oxide film 102 are etched using a gas mixture of CF₄/He/HBr, it is possible to minimize the occurrence of undercuts on an interface between two different material films, i.e. between the tungsten silicide film 110 and the second polycrystalline silicon film 108, between the second polycrystalline silicon film 108 and the OHO film 106, between the ONO film 106 and the first polycrystalline silicon film 104, and between the first polycrystalline silicon film 104 and the silicon oxide film 102, to thereby form a gate having a good profile.

In addition, an in-situ etching of the tungsten silicide film 110, the second polycrystalline silicon film 108, the ONO film 106, the first polycrystalline silicon film 104, and the silicon oxide film 102 within one process chamber using one etchant according to an embodiment of the present invention can reduce processing time required to form a gate over a prior art. Approximately 30 minutes of processing time is required to etch the tungsten silicide film 110, the second polycrystalline silicon film 108, the ONO film 106, the first polycrystalline silicon film 104, and the silicon oxide film 102 by separate steps using two kinds of etchants (SF₆/Cl₂, CHF₃/Ar, and HBr/O₂/HeO₂/He) according to a prior art. On the other hand, it was found that it requires about 2 minutes and 40 seconds of processing time to etch the tungsten silicide film 110, the second polycrystalline silicon film 108, the ONO film 106, the first polycrystalline silicon film 104, and the silicon oxide film 102 with one step using one etchant (CF₄/He/HBr).

The prior art also requires more processing time as well as resulting in the occurrence of particles because of performing an etching process over several steps using many kinds of etchants. However, an embodiment of the present invention can minimize the occurrence of particles and can prevent the contamination of wafers and equipment for etching by in-situ etching a plurality of material films forming a gate with one step using one type of etchant.

As mentioned above, an embodiment of the present invention in-situ etches a tungsten silicide film, polycrystalline silicon films, an OHO film, and a silicon oxide film with one step using one type of etchant having a low etch selectivity on the material films in order to form a gate of a flash memory device. It is possible to prevent undercuts from occurring on an interface between the two different material films to improve cell distribution, minimize the occurrence of particles, and simplify a process, thus maximizing the reliability and productivity of semiconductor memory devices.

What is claimed is:

1. A method for manufacturing a gate of a non-volatile memory device comprising:
forming a stacked material film including a plurality of insulating films and conductive films on an upper side of a semiconductor substrate; and
performing an anisotropic etching process on the stacked material film including the plurality of insulating films and conductive films with one etching process using an etchant having a low etch selectivity on the insulating films and conductive films constituting the stacked material film.

2. The method of claim 1, wherein the stacked material film comprises a silicon oxide film, a first polycrystalline silicon film, an OHO film, a second polycrystalline silicon film, and a tungsten film, which are deposited sequentially on an upper side of a semiconductor substrate.

3. The method of claim 2, wherein said anisotropic etching process comprises performing an in-situ etching sequentially on the tungsten silicide film, the second polycrystalline silicon film, the ONO film, the first polycrystalline silicon film, and the silicon oxide film.

4. The method of claim 3, wherein the silicon oxide film is deposited to a thickness of 100-200 Å, the first silicon oxide film is deposited to a thickness of 600-1000 Å, the ONO film, is deposited to a thickness of 200-250 Å, the second polycrystalline silicon film is deposited to a thickness of 500-700 Å, and the tungsten silicide film, is deposited to a thickness of 800-1200 Å.

5. The method of claim 4, wherein the silicon oxide film is deposited to a thickness of 150 Å, the first silicon oxide film is deposited to a thickness of 800 Å, the ONO film, is deposited to a thickness of 240 Å, the second polycrystalline silicon film is deposited to a thickness of 600 Å, and the tungsten silicide film is deposited to a thickness of 1000 Å.

6. The method of claim 5, wherein a layer formed, of a stacking structure comprising a lower antireflection film, a PEOX film, and an upper antireflection film is further deposited on an upper side of the stacked material film.

7. The method of claim 6, wherein the etchant is a gas mixture comprised of CF₄, He, and HBr.

8. The method of claim 7, wherein the flux of the CF₄, He, and HBr is maintained at 1-500 SCCM.

9. The method of claim 8, wherein the flux of the CF₄, is maintained, at 15-80 SCCM, the flux of the He is maintained at 50-200 SCCM, and the flux of the HBr is maintained, at 100-300 SCCM.

10. The method of claim 9, wherein an RF power is maintained, at 50-1000 W and a pressure is maintained at 5-100 mT within a process chamber performing the etching process.

11. A method for manufacturing a gate of a non-volatile memory device comprising:
forming a stacked material film including a plurality of insulating films and conductive films on an upper side of a semiconductor substrate; and
performing an anisotropic etching process on the stacked material film including the plurality of insulating films and conductive films sequentially from above to below using an etchant having a low etch selectivity on the insulating films and conductive films constituting the stacked material film after the stacked material film is formed on the semiconductor substrate.

12. The method of claim 11, wherein the stacked material film comprises a silicon oxide film, a first polycrystalline silicon film, an ONO film, a second polycrystalline silicon film, and a tungsten film, which are deposited sequentially on an upper side of a semiconductor substrate.

13. The method of claim 12, wherein said performing the anisotropic etching process comprises performing an in-situ etching sequentially on the tungsten silicide film, the second polycrystalline silicon film, the ONO film, the first polycrystalline silicon film, and the silicon oxide film.

14. The method of claim 13, wherein the silicon oxide film is deposited to a thickness of 100-200 Å, the first silicon oxide film is deposited to a thickness of 600-1000 Å, the ONO film is deposited to a thickness of 200-250 Å, the second polycrystalline silicon film is deposited to a thickness of 500-700 Å, and the tungsten silicide film is deposited to a thickness of 800-1200 Å.

15. The method of claim 14, wherein the silicon oxide film is deposited to a thickness of 150 Å, the first silicon oxide film is deposited to a thickness of 800 Å, the ONO film is deposited to a thickness of 240 Å, the second polycrystalline silicon film is deposited to a thickness of 600 Å, and the tungsten silicide film is deposited to a thickness of 1000 Å.

16. The method of claim 15, wherein a hard mask layer formed of a stacking structure comprising a lower antireflection film, a PEOX film, and an upper antireflection film is further deposited on an upper side of the stacked material film.

17. The method of claim 16, wherein the etchant is a mixture gas comprised of CF₄, He, and HBr.

18. The method of claim 17, wherein the flux of the CF₄, He, and HBr is maintained at 1-500 SCCM.

19. The method of claim 18, wherein the flux of the CF₄ is maintained at 15-80 SCCM, the flux of the He is maintained, at 50-200 SCCM, and the flux of the HBr is maintained at 100-300 SCCM.

20. The method of claim 19, wherein an RF power is maintained at 50-1000 W and a pressure is maintained at 5-100 mT within a process chamber performing the etching process.
